(19) United States
(12) Patent Application Publication
(10) Pub. No.: US 2025/0063954 A1
(43) Pub. Date: Feb. 20, 2025

(54) QUANTUM DEVICE AND METHOD OF MANUFACTURING QUANTUM DEVICE

(71) Applicant: Fujitsu Limited, Kawasaki-shi (JP)

(72) Inventors: Akihiko SEKINE, Arakawa (JP); Manabu OHTOMO, Kawasaki (JP)

(73) Assignee: Fujitsu Limited, Kawasaki-shi (JP)

(21) Appl. No.: 18/939,251

(22) Filed: Nov. 6, 2024

Related U.S. Application Data
(63) Continuation of application No. PCT/JP2022/020925, filed on May 20, 2022.

(51) Int. Cl. H10N 60/01; H10N 60/85

(52) U.S. Cl. CPC H10N 60/0884; H10N 60/85

(57) ABSTRACT

A quantum device includes: a higher-order topological insulator layer; and a superconductor layer. The higher-order topological insulator layer has a first surface and a second surface parallel to each other, a third surface that intersects with the second surface and is located closer to a first surface side than the second surface, and a fourth surface that intersects with the third surface and is parallel to the first surface and the second surface, and the superconductor layer is formed over an intersection line of a plane that includes the third surface and the first surface.

### CROSS-REFERENCE TO RELATED APPLICATION

This application is a continuation application of International Application PCT/JP2022/020925 filed on May 20, 2022, and designated the U.S., the entire contents of which are incorporated herein by reference.

### FIELD

The embodiments discussed herein are related to a quantum device and a method of manufacturing the quantum device.

### BACKGROUND

A quantum computation device using a Majorana particle is studied. As a structure for generating the Majorana particle, a structure in which a two-dimensional topological insulator and an s-wave superconductor are combined is proposed. As the two-dimensional topological insulator, a single-layer film of WTe₂, which is a layered material of a transition-metal ditelluride, is used. A study on a higher-order topological insulator layer formed of a multilayer WTe₂ is also conducted.

Japanese Laid-open Patent Publication No. 2020-96107, Japanese National Publication of International Patent Application No. 2020-511780, Japanese Laid-open Patent Publication No. 2013-247267, U.S. Patent Application Publication No. 2021/0257536, and U.S. Patent Application Publication No. 2019/0013457 are disclosed as related art.

Z. Wang, et al., Phys. Rev. Lett. 123, 186401 (2019) and Y.-B. Choi et al., Nat. Mater. 19, 974 (2020) are disclosed as related art.

### SUMMARY

According to an aspect of the embodiments, a quantum device includes: a higher-order topological insulator layer; and a superconductor layer. The higher-order topological insulator layer has a first surface and a second surface parallel to each other, a third surface that intersects with the second surface and is located closer to a first surface side than the second surface, and a fourth surface that intersects with the third surface and is parallel to the first surface and the second surface, and the superconductor layer is formed over an intersection line of a plane that includes the third surface and the first surface.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a plan view illustrating a quantum device according to a first embodiment;

FIG. 2 is a cross-sectional diagram (part 1) illustrating the quantum device according to the first embodiment;

FIG. 3 is a cross-sectional diagram (part 2) illustrating the quantum device according to the first embodiment;

FIG. 4 is a perspective view illustrating a higher-order topological insulator layer according to the first embodiment;

FIG. 5 is a bottom view illustrating the higher-order topological insulator layer and a superconductor layer according to the first embodiment;

FIG. 6 is a cross-sectional diagram (part 1) illustrating a manufacturing method for the quantum device according to the first embodiment;

FIG. 7 is a cross-sectional diagram (part 2) illustrating the manufacturing method for the quantum device according to the first embodiment;

FIG. 8 is a cross-sectional diagram (part 3) illustrating the manufacturing method for the quantum device according to the first embodiment;

FIG. 9 is a cross-sectional diagram (part 4) illustrating the manufacturing method for the quantum device according to the first embodiment;

FIG. 10 is a cross-sectional diagram (part 5) illustrating the manufacturing method for the quantum device according to the first embodiment;

FIG. 11 is a diagram (part 1) illustrating a model used in calculation for a one-dimensional conduction channel;

FIG. 12 is a diagram (part 2) illustrating the model used in the calculation for the one-dimensional conduction channel;

FIG. 13 is a diagram (part 1) illustrating a result of calculation for a higher-order topological insulator layer;

FIG. 14 is a diagram (part 2) illustrating the result of the calculation for the higher-order topological insulator layer;

FIG. 15 is a plan view illustrating a quantum device according to a second embodiment;

FIG. 16 is a cross-sectional diagram illustrating the quantum device according to the second embodiment;

FIG. 17 is a cross-sectional diagram illustrating a quantum device according to a third embodiment;

FIG. 18 is a perspective view illustrating a higher-order topological insulator layer according to a fourth embodiment; and

FIG. 19 is a bottom view illustrating the higher-order topological insulator layer and a superconductor layer according to the fourth embodiment.

### DESCRIPTION OF EMBODIMENTS

The study on the higher-order topological insulator layer in the related art targets a Majorana particle appearing in a one-dimensional conduction channel (helical hinge channel) generated on a side of a rectangular parallelepiped higher-order topological insulator layer. Meanwhile, in a case where the higher-order topological insulator layer is actually formed, arrangement of atoms on the side is more likely to be disordered than arrangement at an inside or a surface. For this reason, the Majorana particles appearing on the side may become unstable.

An object of the present disclosure is to provide a quantum device capable of obtaining a stable Majorana particle and a method of manufacturing the quantum device.

Hereinafter, embodiments of the present disclosure will be specifically described in detail with reference to accompanying drawings. In the present specification and drawings, constituent elements having substantially the same functional configuration may be described with the same reference signs and redundant description thereof may be omitted. In the present disclosure, an X1-X2 direction, a Y1-Y2 direction, and a Z1-Z2 direction are orthogonal to one another. A plane extending in the X1-X2 direction and the Y1-Y2 direction is referred to as an XY plane, a plane extending in the Y1-Y2 direction and the Z1-Z2 direction is referred to as a YZ plane, and a plane extending in the Z1-Z2 direction and the X1-X2 direction is referred to as a ZX plane. For convenience, the Z1-Z2 direction is referred to as an up-down direction, a Z1 side is an upper side, and a Z2 side is a lower side. A plan view refers to a view of a target object from the Z1 side, and a planar shape refers to a shape of the target object as viewed from the Z1 side.

### First Embodiment

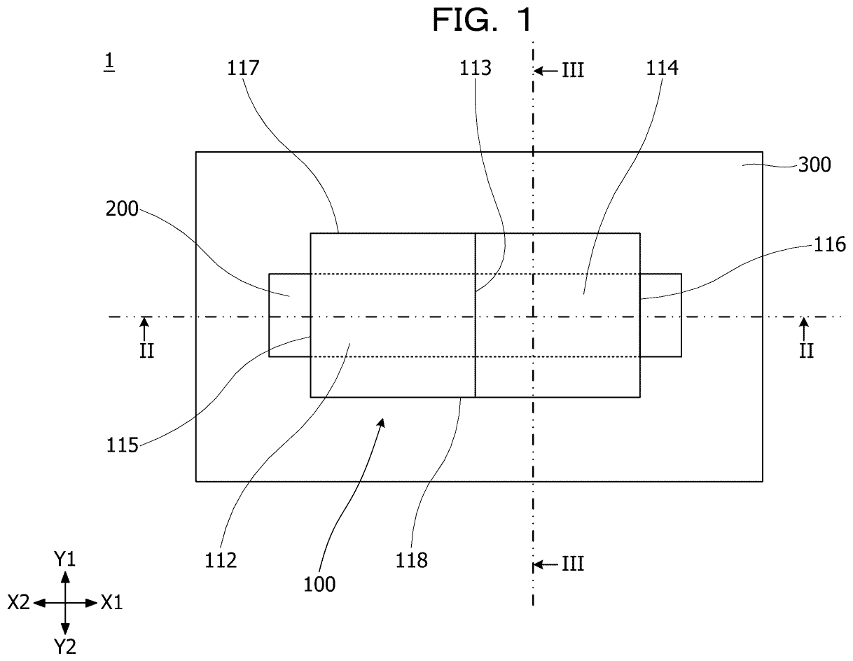

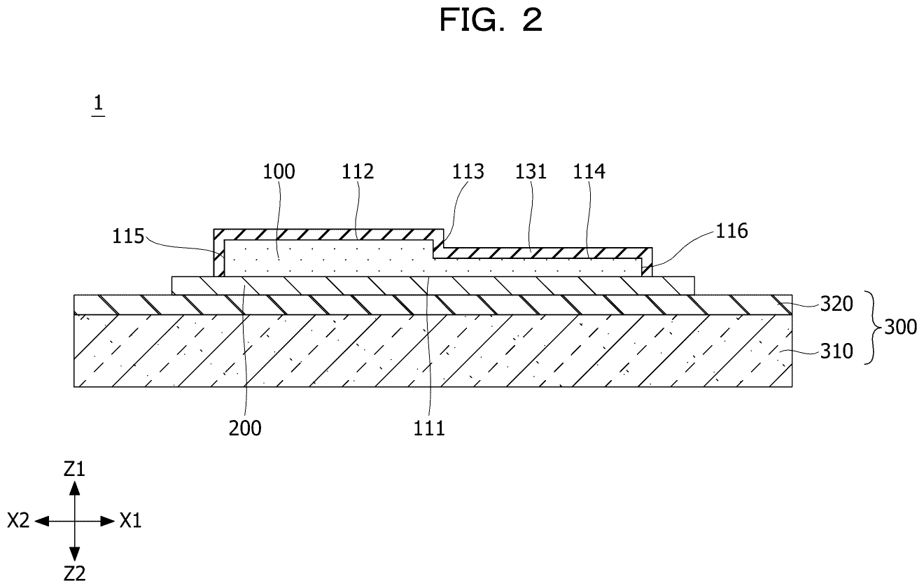

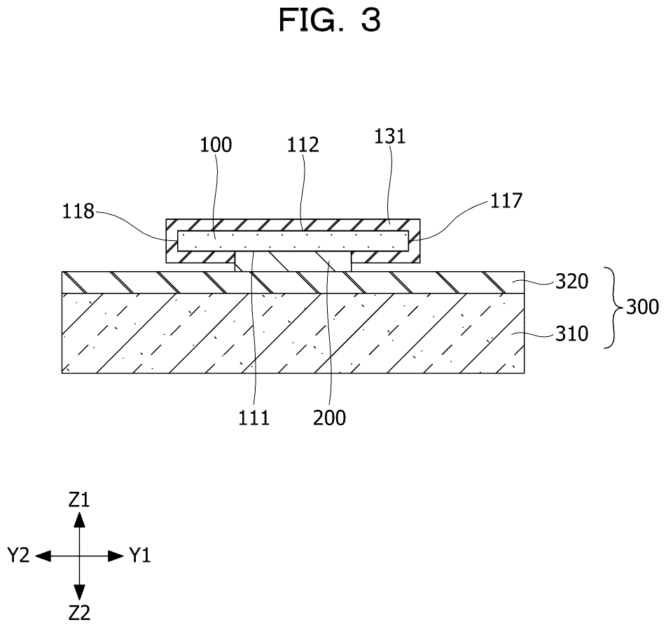

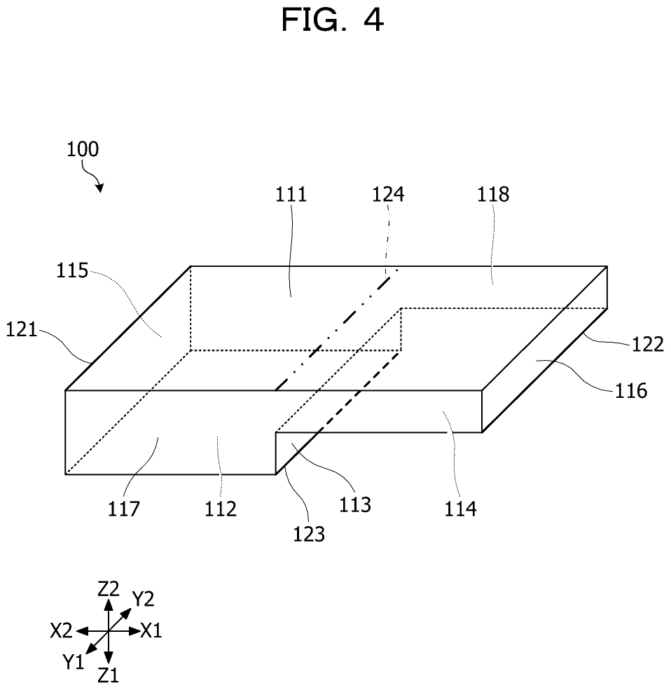

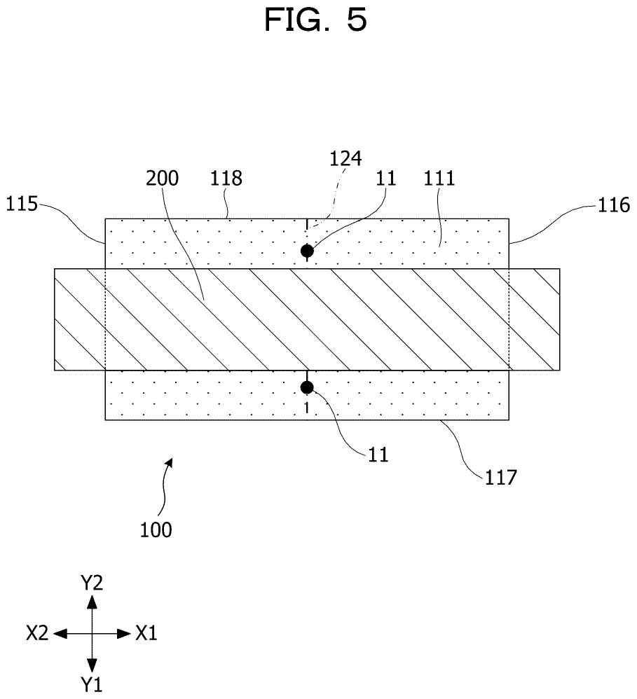

A first embodiment will be described. The first embodiment relates to a quantum device. FIG. 1 is a plan view illustrating the quantum device according to the first embodiment. FIGS. 2 and 3 are cross-sectional diagram s illustrating the quantum device according to the first embodiment. FIG. 4 is a perspective view illustrating a higher-order topological insulator layer according to the first embodiment. FIG. 5 is a bottom view illustrating the higher-order topological insulator layer and a superconductor layer according to the first embodiment. FIG. 1 is a perspective view of a protection layer. FIG. 2 corresponds to a cross-sectional diagram taken along line II-II of FIG. 1. FIG. 3 corresponds to a cross-sectional diagram taken along line III-III of FIG. 1.

A quantum device 1 according to the first embodiment mainly includes a substrate 300, a superconductor layer 200, and a higher-order topological insulator layer 100.

The substrate 300 includes, for example, a silicon (Si) substrate 310 and an insulating film 320. The insulating film 320 is formed over the silicon substrate 310. The insulating film 320 is, for example, a silicon oxide film. The substrate 300 is a so-called substrate with an oxide film. A shape of the substrate 300 is, for example, a rectangular parallelepiped which includes two planes parallel to an XY plane, two planes parallel to a YZ plane, and two planes parallel to a ZX plane, and in which the X1-X2 direction is a longitudinal direction and the Y1-Y2 direction is a lateral direction.

The superconductor layer 200 is provided over the insulating film 320. A shape of the superconductor layer 200 is, for example, a rectangular parallelepiped which includes two planes parallel to an XY plane, two planes parallel to a YZ plane, and two planes parallel to a ZX plane, and in which the X1-X2 direction is a longitudinal direction and the Y1-Y2 direction is a lateral direction. For example, the superconductor layer 200 is an aluminum (Al) layer or a niobium (Nb) layer.

The higher-order topological insulator layer 100 includes a first surface 111, a second surface 112, and a fourth surface 114 that are parallel to the XY plane, a third surface 113, a fifth surface 115, and a sixth surface 116 that are parallel to the YZ plane, and a seventh surface 117 and an eighth surface 118 that are parallel to the ZX plane. The higher-order topological insulator layer 100 is a multilayer WTe₂ (tungsten ditelluride) layer. An a-axis of the WTe₂ is parallel to the Y1-Y2 direction, a b-axis of the WTe₂ is parallel to the X1-X2 direction, and a c-axis of the WTe₂ is parallel to the Z1-Z2 direction. The a-axis, the b-axis, and the c-axis are defined as illustrated in (a) in FIG. 1 of Y.-B. Choi et al., Nat. Mater. 19, 974 (2020).

Shapes of the first surface 111, the second surface 112, and the fourth surface 114 have a rectangular shape having two sides parallel to the X1-X2 direction and two sides parallel to the Y1-Y2 direction. A side of the first surface 111 on the X2 side and a side of the second surface 112 on the X2 side are at the same position in the X1-X2 direction. A side of the first surface 111 on the Y1 side and a side of the second surface 112 on the Y1 side are at the same position in the Y1-Y2 direction, and a side of the first surface 111 on the Y2 side and a side of the second surface 112 on the Y2 side are at the same position in the Y1-Y2 direction. A side of the first surface 111 on the X1 side and a side of the fourth surface 114 on the X1 side are at the same position in the X1-X2 direction. A side of the first surface 111 on the Y1 side and a side of the fourth surface 114 on the Y1 side are at the same position in the Y1-Y2 direction, and a side of the first surface 111 on the Y2 side and a side of the fourth surface 114 on the Y2 side are at the same position in the Y1-Y2 direction. In the Z1-Z2 direction, the fourth surface 114 is closer to the first surface 111 than the second surface 112, and is farther from the second surface 112 than the first surface 111. For example, the fourth surface 114 is located closer to the first surface 111 side than the second surface 112.

Shapes of the third surface 113, the fifth surface 115, and the sixth surface 116 have a rectangular shape having two sides parallel to the Y1-Y2 direction and two sides parallel to the Z1-Z2 direction. The third surface 113 intersects with the second surface 112 and the fourth surface 114. For example, the third surface 113 perpendicularly intersects with the second surface 112 and the fourth surface 114. The fifth surface 115 intersects with the first surface 111 and the second surface 112. For example, the fifth surface 115 perpendicularly intersects with the first surface 111 and the second surface 112. The sixth surface 116 intersects with the first surface 111 and the fourth surface 114. For example, the sixth surface 116 perpendicularly intersects with the first surface 111 and the fourth surface 114.

Shapes of the seventh surface 117 and the eighth surface 118 have a hexagonal shape having three sides parallel to the Z1-Z2 direction and three sides parallel to the X1-X2 direction. All of the seventh surface 117 and the eighth surface 118 intersect with the first surface 111, the second surface 112, the third surface 113, the fourth surface 114, the fifth surface 115, and the sixth surface 116. For example, all of the seventh surface 117 and the eighth surface 118 perpendicularly intersect with the first surface 111, the second surface 112, the third surface 113, the fourth surface 114, the fifth surface 115, and the sixth surface 116. The seventh surface 117 is located on a Y1 side of the eighth surface 118.

In this manner, the higher-order topological insulator layer 100 has a three-dimensional shape in which steps are formed in a rectangular parallelepiped. In the higher-order topological insulator layer 100, one-dimensional conduction channels are generated on sides 121, 122, and 123 indicated by thick lines in FIG. 4. For example, a one-dimensional conduction channel is generated along the side 121 corresponding to an intersection line of the first surface 111 and the fifth surface 115, the side 122 corresponding to an intersection line of the fourth surface 114 and the sixth surface 116, and the side 123 corresponding to an intersection line of the second surface 112 and the third surface 113. In the higher-order topological insulator layer 100, a one-dimensional conduction channel is also generated along an intersection line 124 of a plane including the third surface 113 and the first surface 111.

The higher-order topological insulator layer 100 is provided above the substrate 300 such that the first surface 111 is in contact with an upper surface of the superconductor layer 200. The seventh surface 117 is located closer to the Y1 side than a plane on the Y1 side of the superconductor layer 200, and the eighth surface 118 is located closer to the Y2 side than a plane on the Y2 side of the superconductor layer 200. The fifth surface 115 is located closer to the X2 side than a plane on the X1 side of the superconductor layer 200, and the sixth surface 116 is located closer to the Y1 side than a plane on the Y2 side of the superconductor layer 200. The superconductor layer 200 is close to the intersection line 124. For example, the intersection line 124 is within a range affected by a proximity effect of the superconductor layer 200. For example, the superconductor layer 200 is formed over the intersection line 124 of a plane including the third surface 113 and the first surface 111. As viewed from a direction perpendicular to the first surface 111, the intersection line 124 has a portion protruding from the superconductor layer 200.

A protection layer 131 that covers a surface of the higher-order topological insulator layer 100 is formed. For example, the protection layer 131 is a natural oxide film of WTe₂.

According to the present embodiment, a one-dimensional conduction channel is generated at the intersection line 124 of a plane including the third surface 113 of the higher-order topological insulator layer 100 and the first surface 111. Since the superconductor layer 200 is close to the intersection line 124, a Majorana particle 11 appears at the intersection line 124. For example, the Majorana particle 11 appears at a portion of the intersection line 124, which protrudes from the superconductor layer 200.

Although one-dimensional conduction channels are also generated at the sides 121, 122, and 123, arrangement of atoms in the sides 121, 122, and 123 is likely to be disordered. By contrast, since the intersection line 124 is inside the first surface 111, arrangement of atoms over the intersection line 124 is stable. Accordingly, according to the first embodiment, the stable Majorana particle may be obtained.

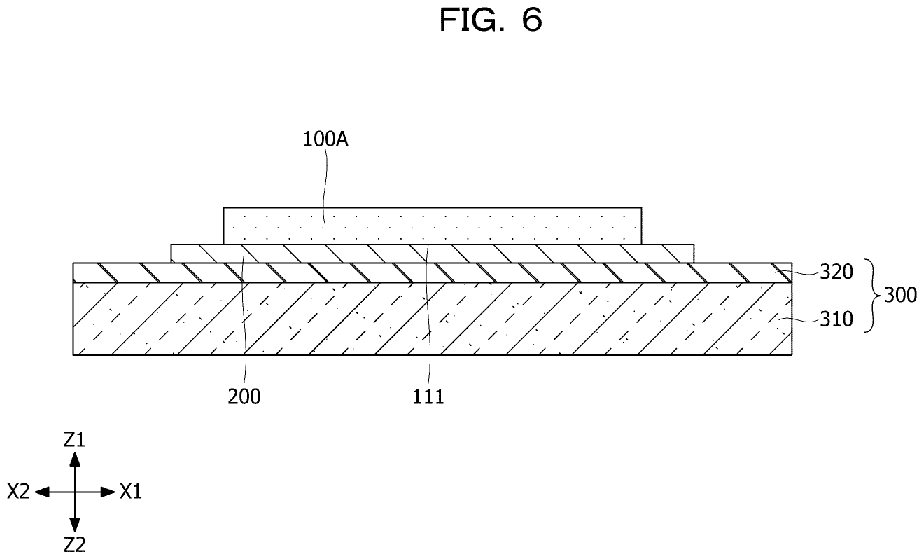

Next, a method of manufacturing the quantum device 1 according to the first embodiment will be described. FIG. 6 to FIG. 10 are cross-sectional diagrams illustrating the method of manufacturing the quantum device 1 according to the first embodiment.

First, as illustrated in FIG. 6, the substrate 300 is prepared, and the superconductor layer 200 is formed over the insulating film 320 of the substrate 300. For example, the superconductor layer 200 may be formed by a lift-off method using a mask. An example of a material of the mask is polymethyl methacrylate (PMMA).

Next, a higher-order topological insulator layer 100A is provided over the superconductor layer 200. The higher-order topological insulator layer 100A is to be the higher-order topological insulator layer 100 later. For example, the higher-order topological insulator layer 100A may be provided over the superconductor layer 200 as follows.

First, tungsten (W) and tellurium (Te) are reacted with each other in a vacuum-sealed tube to produce a single crystal of WTe₂. Next, cleavage using an adhesive tape is repeated to thin the single crystal of WTe₂. As a result of thinning, a plurality of single crystals dispersed in an island shape are obtained from one single crystal. After that, the plurality of single crystals are pressed against a silicon substrate (different from the substrate 300) with an oxide film and heated. As a result, a sample in which a plurality of micron-sized single crystals are dispersed over the silicon substrate with the oxide film is obtained. Among the plurality of single crystals, a single crystal appropriate for forming the higher-order topological insulator layer 100 in terms of thicknesses and planar shapes is selected as the higher-order topological insulator layer 100A. Subsequently, the higher-order topological insulator layer 100A is bonded to a polymer dome tool with an adhesive layer and lifted. The polymer dome tool with the adhesive layer is, for example, a tool in which a droplet of polydimethylsiloxane (PDMS) is dropped over a glass substrate to be molded into a dome shape, and a polymer film is attached thereon. For example, the polymer film is a polycarbonate (PC) film.

Next, the higher-order topological insulator layer 100A bonded to the polymer dome tool with an adhesive layer is pressed onto the superconductor layer 200, and the polymer film dissolves by heating. For example, when the polymer film is a PC film, a heating temperature is 180° C. As a result, the higher-order topological insulator layer 100A is provided over the superconductor layer 200 together with the polymer film. After that, the polymer film is removed. For example, in a case where the polymer film is a PC film, the polymer film may be removed by dissolution with chloroform.

For example, the higher-order topological insulator layer 100A may be directly formed by a molecular beam epitaxy (MBE) method or a pulse laser deposition (PLD) method. In this case, for example, the higher-order topological insulator layer 100A is formed only at a desired position by using a contact mask or the like.

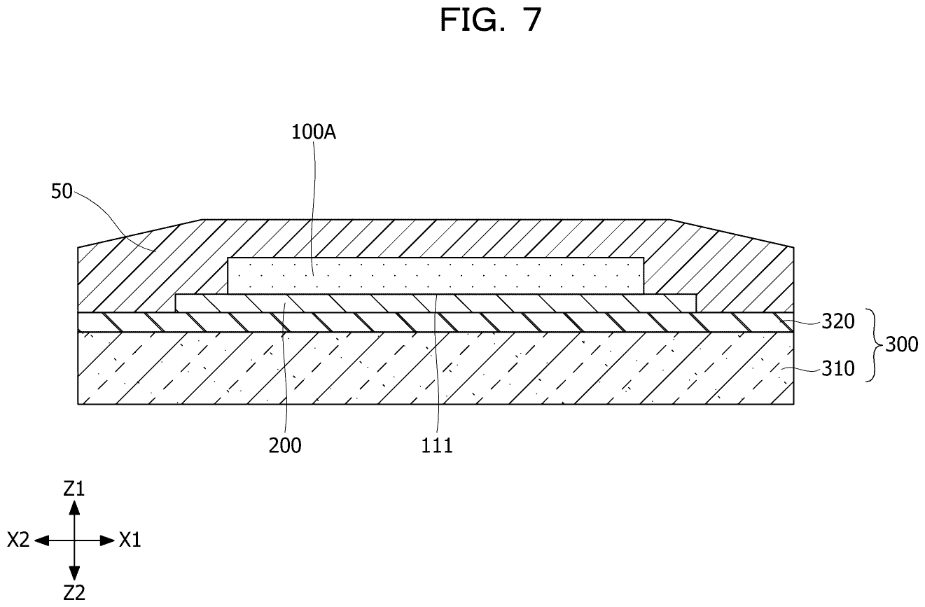

After the higher-order topological insulator layer 100A is provided over the superconductor layer 200, as illustrated in FIG. 7, an electron-beam resist film 50 that covers the higher-order topological insulator layer 100A and the superconductor layer 200 is formed over the insulating film 320. A material of the electron-beam resist film 50 is, for example, ZEP-520A manufactured by Zeon Corporation or XR-1541 manufactured by Dow Corning Corporation in Japan. For example, the electron-beam resist film 50 may be formed by a spin coating method.

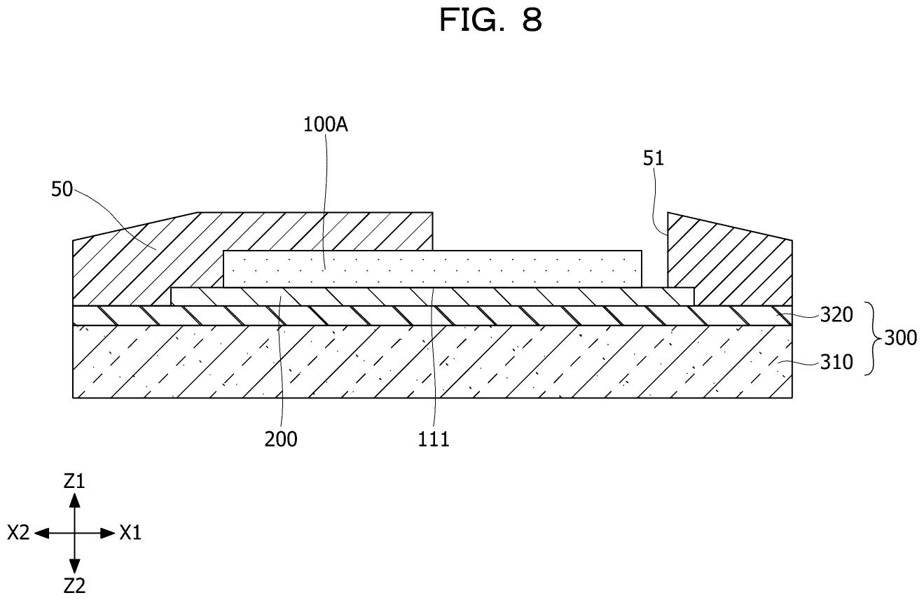

As illustrated in FIG. 8, an opening portion 51 that exposes a region in which the fourth surface 114 is to be formed is formed in the electron-beam resist film 50 by exposure and development using an electron beam drawing apparatus.

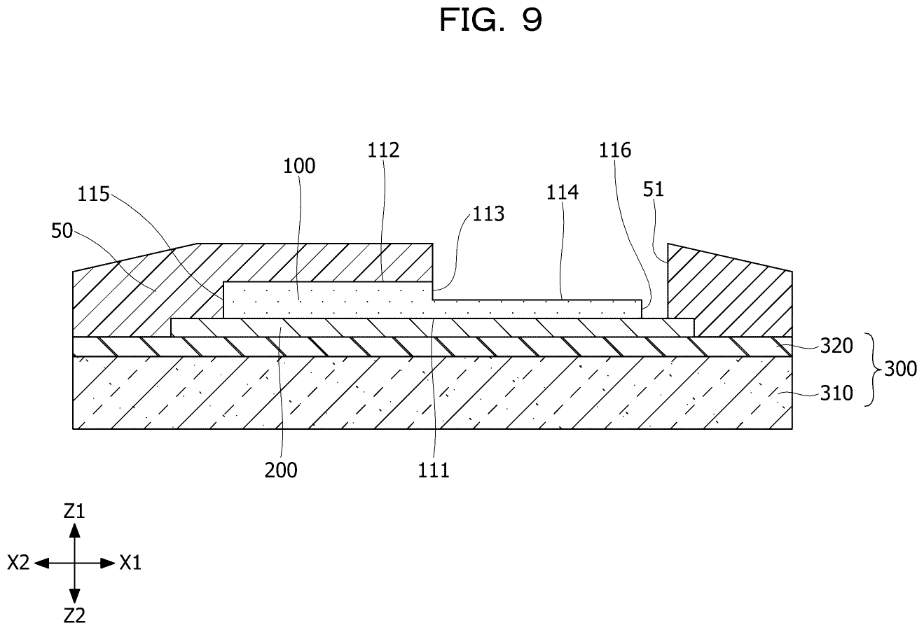

After that, as illustrated in FIG. 9, milling with argon (Ar) molecules is performed by using a reactive ion etching apparatus to form the third surface 113, the fourth surface 114, and the sixth surface 116 in the higher-order topological insulator layer 100A. A remaining portion of the higher-order topological insulator layer 100A is the second surface 112. As a result, the higher-order topological insulator layer 100 is obtained from the higher-order topological insulator layer 100A. During the milling, a recess portion may be formed in the superconductor layer 200 and the substrate 300.

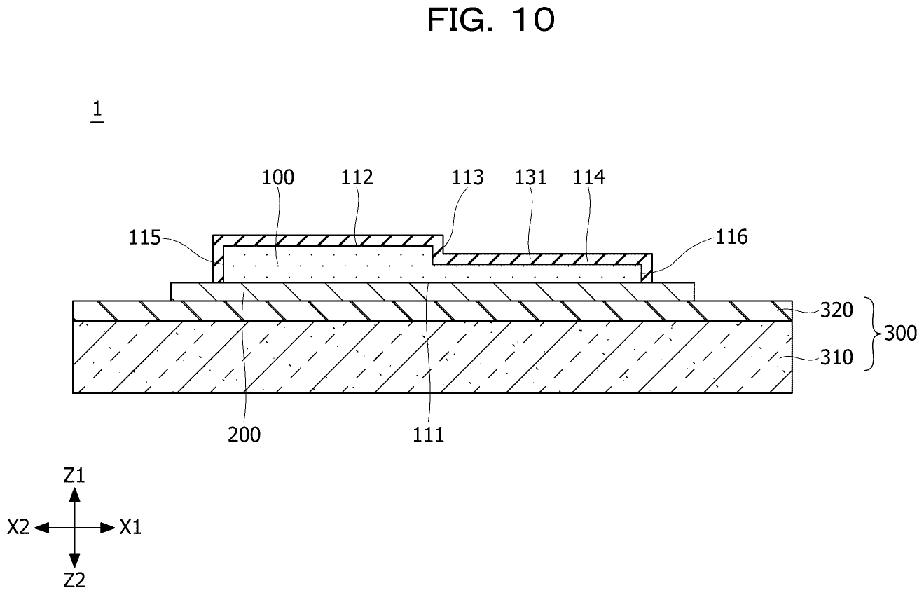

As illustrated in FIG. 10, the electron-beam resist film 50 is removed, and the protection layer 131 is formed over a surface of the higher-order topological insulator layer 100. For example, the protection layer 131 may be formed by natural oxidation. In a case where the sixth surface 116 is not a flat surface in the step illustrated in FIG. 9, the sixth surface 116 may be a flat surface by processing using another mask after the electron-beam resist film 50.

In this manner, the quantum device 1 according to the first embodiment may be manufactured.

A calculation for the one-dimensional conduction channel of WTe₂ performed by the inventor of the present application will be described. For this calculation, hamiltonian H (k) in Equation (1) is used (see Z. Wang, et al., Phys. Rev. Lett. 123, 186401 (2019) and Y.-B. Choi et al., Nat. Mater. 19, 974 (2020)). m₁, m₂, m₃, vₐ, v_{b}, v_{c}, Δ_{b}, Δ_{c}, γₓ, γ_{z}, and Ba are parameters unique to substances, and μi, τi, and σi are Pauli matrices of 2×2.

$$H ( k ) = ( {m}_{1} + {\sum }_{j = a , b , c} {v}_{j} cos {k}_{j} + {m}_{2} {μ}_{x} + {m}_{3} {μ}_{z} ) {τ}_{z} + {λ}_{b} sin {k}_{b} {μ}_{y} {τ}_{y} + {λ}_{c} sin {k}_{c} {τ}_{x} + {γ}_{x} {μ}_{x} + {γ}_{z} {μ}_{z} + {β}_{a} sin {k}_{a} {μ}_{z} {τ}_{y} {σ}_{z} \qquad ( 1 )$$

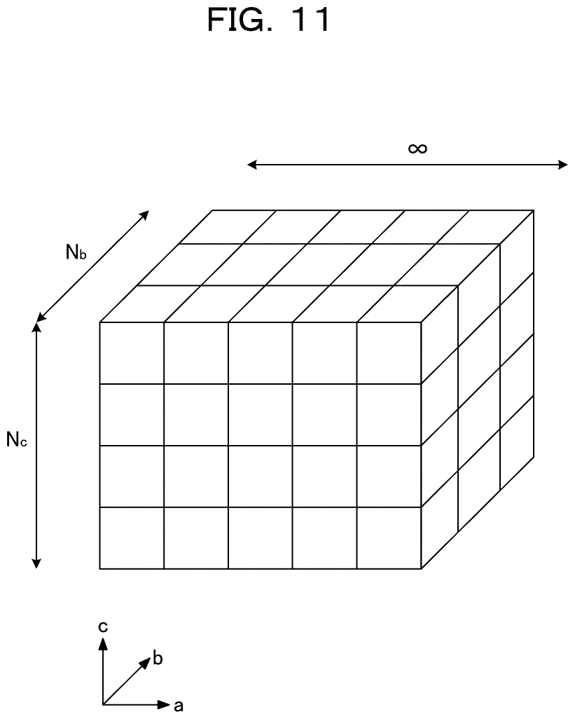

As illustrated in FIG. 11, the hamiltonian H (k) is limited to a size in which the number of sites in a direction parallel to the b-axis of WTe₂ is N_{b} and the number of sites in a direction parallel to the c-axis is N_{c} by strongly constrained approximation (see Equation 2).

$$H = {\sum }_{k} {Ψ}_{k}^{†} H ( k ) {Ψ}_{k} \to H = {\sum }_{{k}_{a}} {Ψ}_{{k}_{a}}^{†} {H}_{lattice} ( {k}_{a} ) {Ψ}_{{k}_{a}} \qquad ( 2 )$$

Next, the matrix H_{lattice}(kₐ) in Equation (2) is diagonalized. At this time, a parameter unique to WTe₂ is substituted for m₁, m₂, m₃, vₐ, v_{b}, v_{c}, λ_{b}, λ_{c}, γₓ, γ_{z}, and βₐ. In this manner, 8×N_{b}×N_{c} eigenvalues Eₙ(kₐ) and an eigenvector ψₙ(kₐ) are obtained for the wave number kₐ.

After that, when the eigen energy (eigenvalue Eₙ(kₐ)) is plotted as a function of the wave number kₐ, energy dispersion of the entire system is obtained. By contour-plotting the square of the absolute values of the eigenvector (|ψₙ (kₐ)|²) corresponding to a state n in which the energy dispersion is linear (Eₙ(kₐ)∝kₐ) with respect to a wave number, it is found where an electron exists in WTe₂.

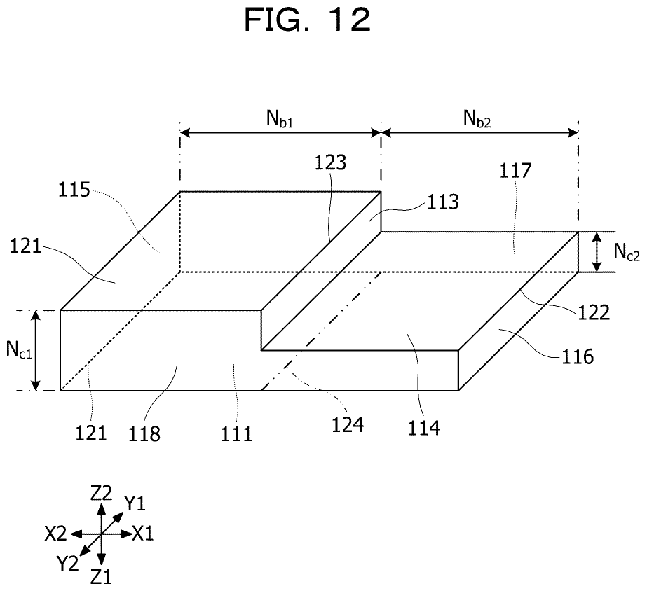

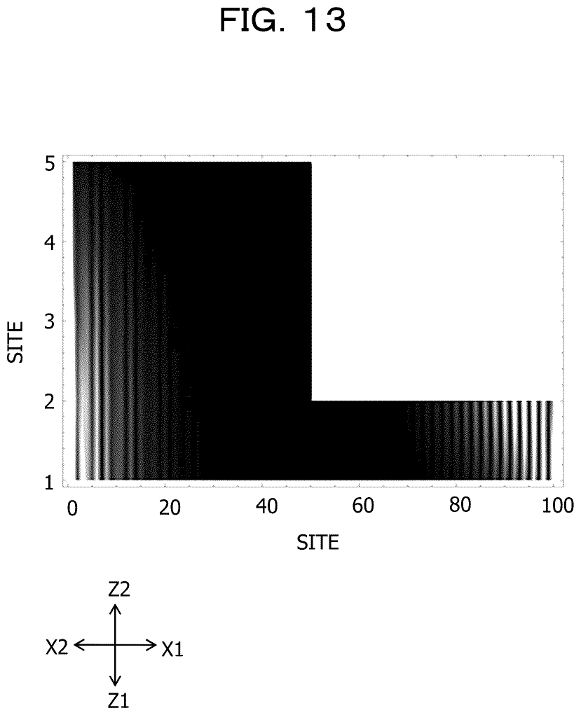

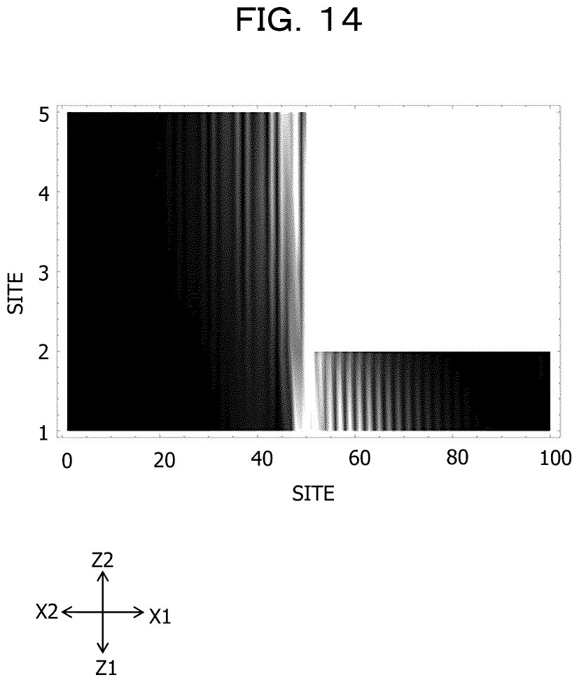

Calculation results for the higher-order topological insulator layer 100 are illustrated in FIGS. 13 and 14. FIGS. 13 and 14 illustrate that electrons are more likely to exist at a brighter portion. In this calculation, as illustrated in FIG. 12, the number N_{b1} of sites corresponding to a distance between the third surface 113 and the fifth surface 115 is set to 50, the number N_{b2} of sites corresponding to a distance between the third surface 113 and the sixth surface 116 is set to 50, the number N_{c1} of sites corresponding to a distance between the first surface 111 and the second surface 112 is set to 5, and the number N_{c2} of sites corresponding to a distance between the first surface 111 and the fourth surface 114 is set to 2. It is apparent that electrons are likely to exist not only at a portion corresponding to the side 121 and a portion corresponding to the side 122 as illustrated in FIG. 13, but also at a portion corresponding to the side 123 and a portion corresponding to the intersection line 124 as illustrated in FIG. 14. Also from this calculation result, it may be seen that a one-dimensional conduction channel is generated at the intersection line 124.

### Second Embodiment

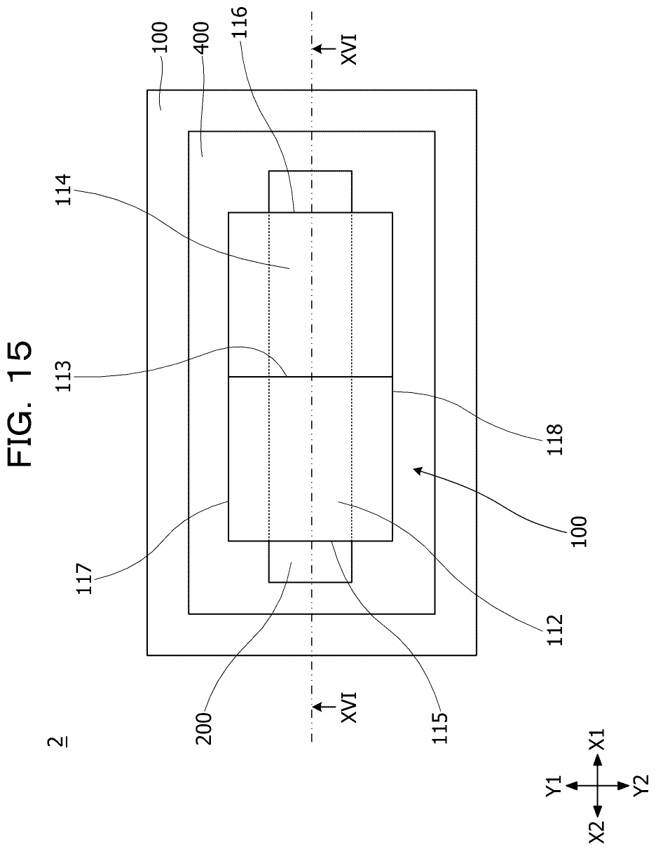

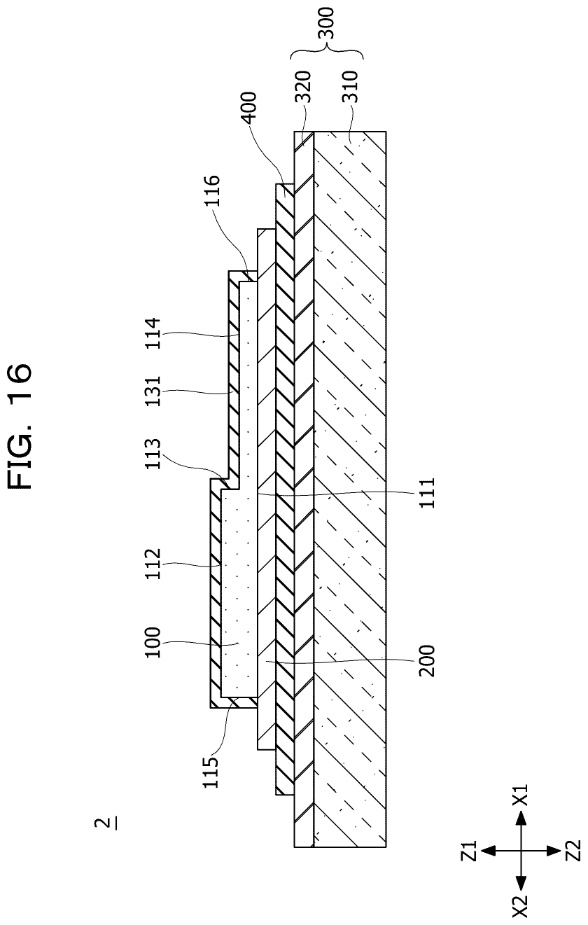

A second embodiment will be described. The second embodiment is different from the first embodiment mainly in a configuration between the substrate 300 and the superconductor layer 200. FIG. 15 is a plan view of a quantum device according to the second embodiment. FIG. 16 is a cross-sectional diagram illustrating the quantum device according to the second embodiment. FIG. 15 is a perspective view of a protection layer. FIG. 16 corresponds to a cross-sectional diagram taken along line XVI-XVI of FIG. 15.

In a quantum device 2 according to the second embodiment, a hexagonal boron nitride (h-BN) layer 400 is provided over the insulating film 320 of the substrate 300, and the superconductor layer 200 and the higher-order topological insulator layer 100 are provided over the hexagonal boron nitride layer 400. For example, the hexagonal boron nitride layer 400 may be manufactured from a single crystal of h-BN in the same manner as the higher-order topological insulator layer 100A according to the first embodiment. Alternatively, the hexagonal boron nitride layer 400 may be manufactured by a chemical vapor deposition (CVD) method.

Other configurations have the same manner as the configurations of the first embodiment.

Also according to the second embodiment, effects similar to those of the first embodiment may be obtained. According to the second embodiment, since the hexagonal boron nitride layer 400 is provided, electron transport characteristics of the higher-order topological insulator layer 100 may be improved.

### Third Embodiment

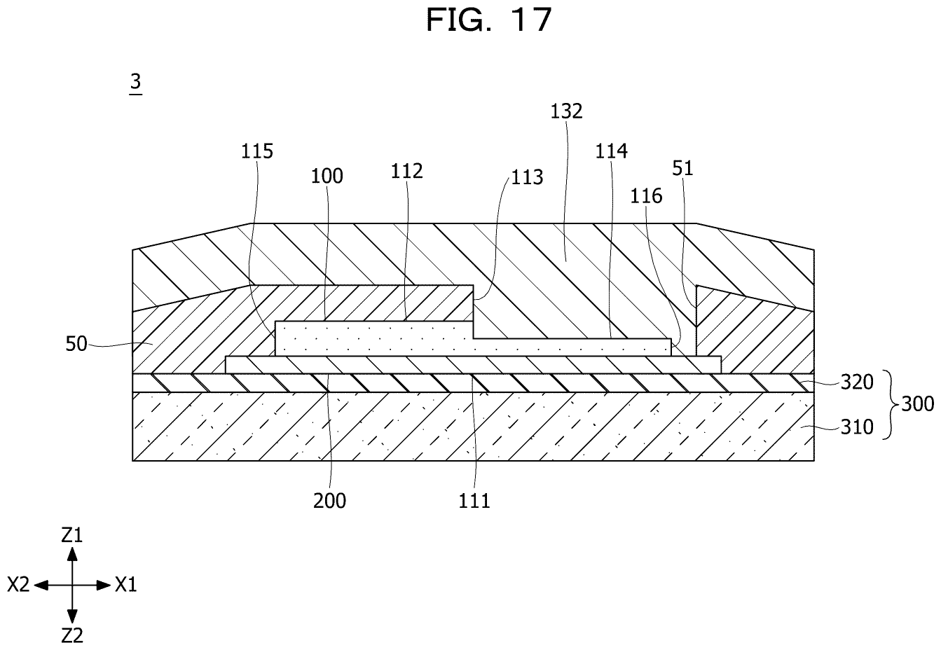

A third embodiment will be described. The third embodiment is different from the first embodiment mainly in a configuration of a protection layer. FIG. 17 is a cross-sectional diagram of a quantum device according to the third embodiment.

A quantum device 3 according to the third embodiment includes a protection layer 132 instead of the protection layer 131. The electron-beam resist film 50 used in the middle of the manufacture of the first embodiment is not removed and remains. The protection layer 132 has a portion that fills an inside of the opening portion 51 and a portion over the electron-beam resist film 50. For example, the protection layer 131 is a parylene layer.

Other configurations have the same manner as the configurations of the first embodiment.

Also according to the third embodiment, effects similar to those of the first embodiment may be obtained. Even in a case where it is difficult to remove the electron-beam resist film 50, the electron-beam resist film 50 may not be removed as it is. Accordingly, a damage or the like due to the removal of the electron-beam resist film 50 may be avoided.

### Fourth Embodiment

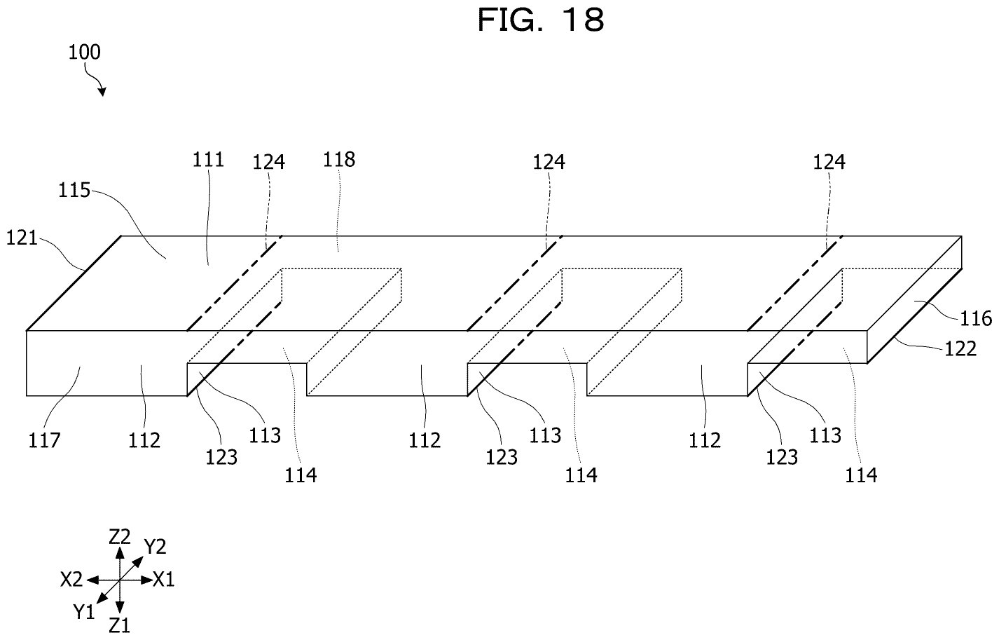

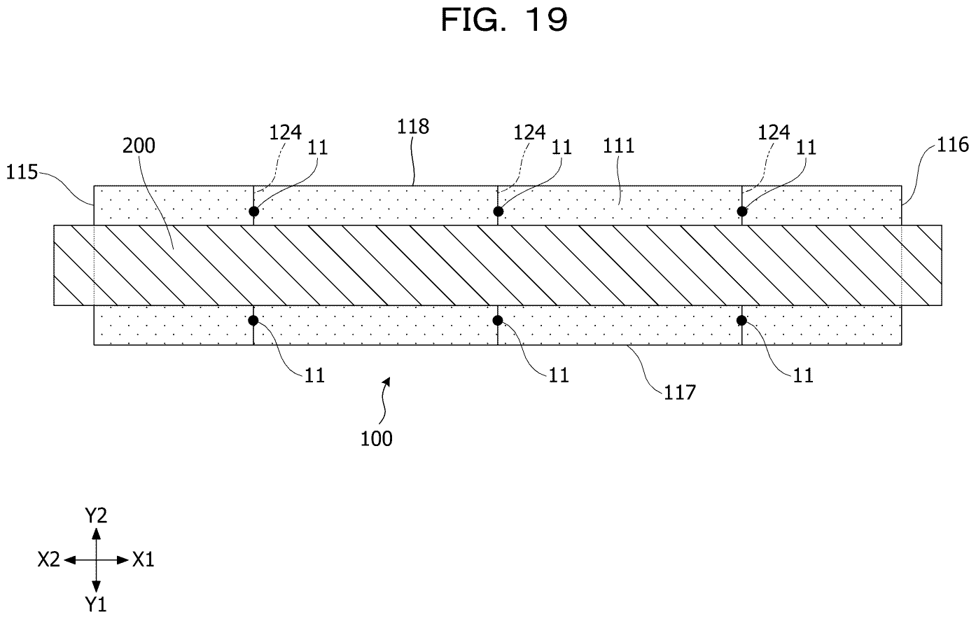

A fourth embodiment will be described. The fourth embodiment is different from the first embodiment mainly in a configuration of a higher-order topological insulator layer. FIG. 18 is a perspective view illustrating a higher-order topological insulator layer according to the fourth embodiment. FIG. 19 is a bottom view illustrating the higher-order topological insulator layer and a superconductor layer according to the fourth embodiment.

According to the fourth embodiment, the higher-order topological insulator layer 100 includes a plurality of sets (here, three sets) of the second surface 112, the third surface 113, and the fourth surface 114. Accordingly, there are a plurality of, here, three, the intersection lines 124 between a plane including the third surface 113 and the first surface 111. The superconductor layer 200 is close to each of the intersection lines 124.

Other configurations have the same manner as the configurations of the first embodiment.

Also according to the fourth embodiment, effects similar to those of the first embodiment may be obtained. According to the fourth embodiment, a plurality of one-dimensional conduction channels may be generated at one first surface 111 of the higher-order topological insulator layer 100. Accordingly, a large number of the Majorana particles 11 may appear. For this reason, the fourth embodiment is appropriate for increasing the number of quantum bits and increasing a density of the quantum bits.

One superconductor layer 200 does not have to be close to all the intersection lines 124, and the superconductor layers close to the respective intersection lines 124 may be independently separated from each other. For example, three superconductor layers 200 may be provided.

A material of the higher-order topological insulator layer 100 is not limited to WTe₂. For example, the material of the higher-order topological insulator layer 100 may be MoTe₂ or Bi. In a case where the higher-order topological insulator layer 100 is a multilayer MoTe₂ layer, the intersection line 124 is preferably parallel to the a-axis of the MoTe₂. In a case where the higher-order topological insulator layer 100 is a multilayer Bi layer, the intersection line 124 is preferably parallel to the [111]-axis of Bi.

Although the preferred embodiments and the like have been described in detail above, the present disclosure is not limited to the embodiments described above and the like. Various modifications and replacements may be made to the above-described embodiments and the like without departing from the scope of the claims.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A quantum device comprising:
a higher-order topological insulator layer; and
a superconductor layer,
wherein the higher-order topological insulator layer has
a first surface and a second surface parallel to each other,
a third surface that intersects with the second surface and is located closer to a first surface side than the second surface, and
a fourth surface that intersects with the third surface and is parallel to the first surface and the second surface, and
the superconductor layer is formed over an intersection line of a plane that includes the third surface and the first surface.

2. The quantum device according to claim 1,
wherein the intersection line has a portion that protrudes from the superconductor layer as viewed in a direction perpendicular to the first surface.

3. The quantum device according to claim 1,
wherein the third surface perpendicularly intersects with the second surface.

4. The quantum device according to claim 1,
wherein the fourth surface perpendicularly intersects with the third surface.

5. The quantum device according to claim 1,
wherein the higher-order topological insulator layer includes a plurality of sets of the second surface, the third surface, and the fourth surface, and
the superconductor layer is close to an intersection line of a plane that includes each of a plurality of the third surfaces and the first surface.

6. The quantum device according to claim 1,
wherein the higher-order topological insulator layer includes a multilayer WTe₂ layer or a multilayer MoTe₂ layer.

7. The quantum device according to claim 6,
wherein an intersection line of the second surface and the third surface is parallel to an a-axis of WTe₂ or MoTe₂.

8. The quantum device according to claim 1,
wherein the higher-order topological insulator layer includes a multilayer Bi layer.

9. The quantum device according to claim 8,
wherein an intersection line of the second surface and the third surface is parallel to a [111]-axis of Bi.

10. A method of manufacturing a quantum device, the method comprising:
forming, by processing a higher-order topological insulator layer that includes a first surface,
a second surface parallel to the first surface,
a third surface that intersects with the second surface and is located closer to a first surface side than the second surface, and
a fourth surface that intersects with the third surface and is parallel to the first surface and the second surface; and
forming a superconductor layer over an intersection line of a plane that includes the third surface and the first surface.
